(19) United States
(12) Patent Application Publication
(10) Pub. No.: US 2025/0216428 A1
(43) Pub. Date: Jul. 3, 2025

(54) REPRESENTATIVE FREQUENCIES DETERMINATION FOR ESTIMATING EMISSION POWER FROM ANTENNA ARRAY

(71) Applicant: SAMSUNG ELECTRONICS CO., LTD., SUWON-SI (KR)

(72) Inventors: DONGKWON CHOI, Suwon-si (KR); HONGKOO LEE, Suwon-si (KR); JUSEONG PARK, Suwon-si (KR); YOUNGKI LEE, Suwon-si (KR); WONCHEOL JEONG, Suwon-si (KR); SANGGYU HA, Suwon-si (KR); JOONHOI HUR, Suwon-si (KR)

(21) Appl. No.: 18/966,941

(22) Filed: Dec. 3, 2024

(30) Foreign Application Priority Data
Dec. 29, 2023 (KR) 10-2023-0197623
May 13, 2024 (KR) 10-2024-0062782

(51) Int. Cl. G01R 23/18; H04W 52/52

(52) U.S. Cl. CPC G01R 23/18; H04W 52/52

(57) ABSTRACT

An operating method of a representative frequency determination device determining a plurality of representative frequencies used by a communication device to estimate total emission power from an antenna array may be provided. The method may comprise generating, based on a first sample communication device corresponding to the communication device, an ideal correction value table including a plurality of ideal correction values respectively corresponding to a plurality of frequencies, and determining the plurality of representative frequencies such that errors of a plurality of interpolation correction values for the plurality of ideal correction values to be less than a first threshold error, wherein the plurality of interpolation correction values are generated by interpolating a first plurality of ideal correction values, among the plurality of ideal correction values, corresponding to the plurality of representative frequencies.

### CROSS-REFERENCE TO RELATED APPLICATION

This application claims priority to and the benefit of Korean Patent Application No. 10-2023-0197623 filed in the Korean Intellectual Property Office on Dec. 29, 2023, and Korean Patent Application No. 10-2024-0062782 filed in the Korean Intellectual Property Office on May 13, 2024, the entire contents of which are incorporated by reference herein.

### FIELD

The present disclosure relates generally to a wireless communication device and more particularly, to determine a plurality of representative frequencies.

### DISCUSSION OF THE RELATED ART

Frequencies used by today's communication devices are gradually increasing to increase data transmission throughput in accordance with the development of wireless communication technology. However, as the frequencies used by the communication device increases, a transmission loss occurring during wireless communication may increase. Accordingly, it is becoming increasingly important to precisely determine and adjust a magnitude of power emitted from an antenna by considering the transmission loss which occurs during the wireless communication.

The communication device may estimate the magnitude of the power emitted from an antenna array and may adjust a magnitude of the power emitted from the antenna array based on the estimation result. To this end, the communication device is required to accurately estimate the magnitude of the power emitted from the antenna array to adjust the magnitude of the power emitted from the antenna array.

The communication device may store a plurality of representative correction values, each corresponding to one of a plurality of representative frequencies. The communication device may determine a correction value for any frequency based on the plurality of representative correction values. The communication device may estimate the magnitude of the power emitted from the antenna array based on the determined correction value. However, the magnitude of the power emitted from the antenna array may be estimated inaccurately if the plurality of representative frequencies are not properly determined.

### SUMMARY

Embodiments of the present disclosure provide a representative frequency determination device determining a plurality of representative frequencies, an operating method thereof, and a communication device operating based on the plurality of representative frequencies.

According to an aspect, operating method of a representative frequency determination device determining a plurality of representative frequencies used by a communication device to estimate total emission power from an antenna array may be provided. The method may comprise: generating, based on a first sample communication device corresponding to the communication device, an ideal correction value table including a plurality of ideal correction values respectively corresponding to a plurality of frequencies; and determining the plurality of representative frequencies estimation such that errors of a plurality of interpolation correction values for the plurality of ideal correction values are less than a threshold error, wherein the plurality of interpolation correction values are generated by interpolating between a first plurality of ideal correction values, among the plurality of ideal correction values, corresponding to the plurality of representative frequencies.

According to an aspect, a communication device connected to an antenna array including first to k-th antennas may be provided. The device may comprise: first to k-th amplifiers respectively configured to provide, to first to k-th antennas, first to k-th amplified input signals which are generated by amplifying the first to k-th input signals having a target frequency; and first to k-th power detector circuits respectively configured to generate first to k-th detection power values by detecting powers of the first to k-th amplified input signals; a memory circuit configured to store a first representative correction value corresponding to a first representative frequency less than the target frequency and a second representative correction value corresponding to a second representative frequency greater than the target frequency; an interpolation circuit configured to calculate a target interpolation correction value corresponding to the target frequency by performing linear interpolation between the first and second representative correction values; and a gain control circuit configured to control gains of the first to k-th amplifiers based on the target interpolation correction value, Wherein the first and second representative frequencies are determined by segmented linear regression analysis for a plurality of ideal correction values, respectively corresponding to a plurality of frequencies different each other, of a first sample communication device corresponding to the communication device.

According to an aspect, a representative frequency determination device determining a plurality of representative frequencies used by a communication device to estimate a total emission power from an antenna array may be provided. The device may comprise: a correction value calculation circuit configured to generate a first ideal correction value table including a first plurality of ideal correction values respectively corresponding to a plurality of frequencies based on a first sample communication device corresponding to the communication device, and to generate a second ideal correction value table including a second plurality of ideal correction values respectively corresponding to the plurality of frequencies based on a second sample communication device corresponding to the communication device; a representative frequency determination circuit configured to determine a first plurality of representative frequencies based on the first ideal correction value table, and to determine a second plurality of representative frequencies based on the second ideal correction value table; and a representative frequency merging circuit configured to generate the plurality of representative frequencies based on the first plurality of representative frequencies and the second plurality of representative frequencies.

### BRIEF DESCRIPTION OF THE DRAWINGS

FIG. 1 is a block diagram showing a communication system according to an embodiment of the present disclosure.

FIG. 2 is a block diagram showing a portion of the configuration shown in FIG. 1 in more detail.

FIG. 3 is a block diagram showing a configuration of a communication power control module shown in FIG. 1 in more detail.

FIG. 4 is a drawing showing a representative correction value table shown in FIG. 1 in more detail.

FIG. 5 is a drawing showing an operation of an interpolation circuit shown in FIG. 3 in more detail.

FIG. 6 is a drawing showing a correction value calculation system for calculating a plurality of representative correction values shown in FIG. 5.

FIG. 7 is a block diagram showing a representative frequency determination system for determining a plurality of representative frequencies shown in FIG. 4.

FIG. 8 is a drawing showing the ideal correction value table shown in FIG. 7 in more detail.

FIG. 9 is a graph showing a plurality of ideal correction values shown in FIG. 8.

FIGS. 10 and 11 are diagrams showing a relationship between interpolation correction values generated by linearly interpolating the ideal correction values corresponding to the representative frequencies and the ideal correction values, shown in FIG. 9.

FIG. 12 is a drawing showing a target interpolation correction value generated based on the determined representative frequency according to an embodiment of the present disclosure.

FIG. 13 is a drawing showing a control method of a communication device according to an embodiment of the present disclosure.

FIG. 14 is a drawing showing operation S100 shown in FIG. 13 in more detail.

FIG. 15 is a drawing showing operation S200 shown in FIG. 13 in more detail.

FIG. 16 is a drawing showing operation S300 shown in FIG. 13 in more detail.

FIG. 17 is a block diagram showing the representative frequency determination system for determining a plurality of representative frequencies shown in FIG. 4 according to an embodiment.

FIG. 18 is a block diagram showing a more detailed configuration of an electronic device according to an embodiment.

### DETAILED DESCRIPTION OF EMBODIMENTS

Hereinafter, embodiments of the present disclosure are described clearly and in detail for those skilled in the art to which the present disclosure pertains to easily implement the present disclosure. Details such as detailed configurations and structures are provided only to facilitate a general understanding of the embodiments of the present disclosure. Therefore, modifications of the embodiments described herein may be performed by those skilled in the art without departing from the spirit and scope of the present disclosure. Moreover, the description omits descriptions of well-known functions and structures for clarity and conciseness. Components in the following drawings or detailed description may be connected with other components other than those shown in the drawings or described in the detailed description. Terms used in the specification are terms defined in consideration of their functions in the present disclosure, and are not limited to specific functions. Definitions of the terms may be determined based on details described in the detailed description.

Components described with reference to terms such as a driver or a block used in the detailed description may be implemented in software, hardware, or a combination thereof. Illustratively, the software may be a machine code, a firmware, an embedded code, or application software. For example, the hardware may include an electrical circuit, an electronic circuit, a processor, a computer, integrated circuit cores, a pressure sensor, an inertial sensor, a micro electromechanical systems (MEMS), a passive component, or a combination thereof.

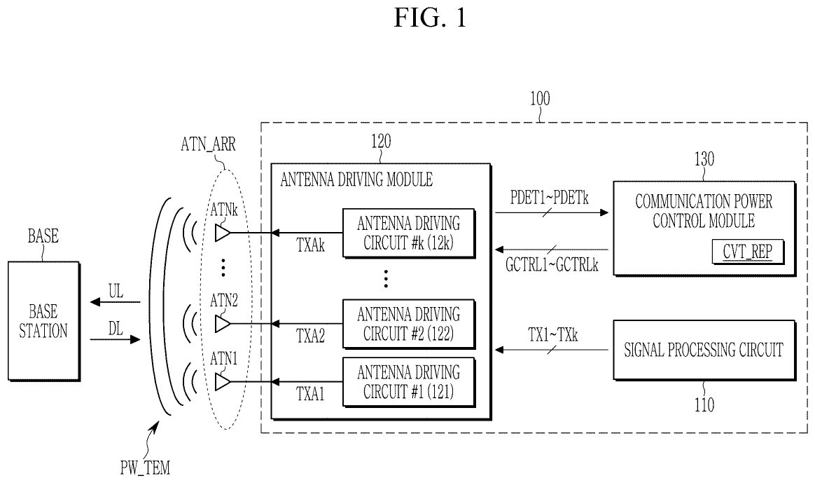

FIG. 1 is a block diagram showing a communication system according to an embodiment of the present disclosure. Referring to FIG. 1, the communication system may include a base station BASE and a communication device 100.

The base station BASE may refer to a fixed station that communicates with any type of user device and/or other base stations. The base station BASE may communicate with another user device and/or other base stations to exchange data.

The communication device 100 may communicate with the base station BASE to exchange the data. For example, the communication device 100 may be included in any type of wireless communication device, such as a smartphone, a laptop, a navigation device, or a tablet personal computer.

The base station BASE and the communication device 100 may communicate with each other in a wireless manner. For example, the base station BASE and the communication device 100 may communicate with each other based on wireless communication protocols of various types, such as 5th generation wireless (5G) and long term evolution (LTE). However, the scope of the present disclosure is not limited thereto. For example, the base station BASE and the communication device 100 may communicate with each other based on the wireless communication protocol of any type, such as code division multiple access (CDMA), global system for mobile communications (GSM), or wireless personal area network (WPAN).

The communication device 100 may transmit uplink data to the base station BASE through an uplink (UL) channel and receive downlink data from the base station BASE through a downlink (DL) channel. Each transmission loss in the uplink UL and the downlink DL may depend on a frequency used for the communication between the base station BASE and the communication device 100.

Meanwhile, power consumption of the communication device 100 may depend on power of a signal transmitted by the communication device 100 through the uplink UL. For example, the power consumption of the communication device 100 may increase as the power of the signal transmitted by the communication device 100 through the uplink UL increases, and vice versa.

The communication device 100 may appropriately adjust the power of the signal to be transmitted uplink by considering its power consumption and the transmission loss in the uplink. For example, the communication device 100 may adjust the signal to be transmitted uplink to have a low enough power level to prevent unnecessary power consumption, and adjust the signal to be transmitted uplink to have a high enough power level to prevent a communication failure between the base station BASE and the communication device 100 caused by the uplink transmission. Hereinafter, a method for adjusting the power level of the signal to be transmitted by the communication device 100 uplink will be described.

The communication device 100 may include a signal processing circuit 110, an antenna driving circuit (“module”) 120, and a communication power control circuit (“module”) 130.

The signal processing circuit 110 may generate first to k-th input signals TX1 to TXk. The signal processing circuit 110 may provide the first to k-th input signals TX1 to TXk to the antenna driving module 120.

The antenna driving module 120 may drive an antenna array ATN_ARR. For example, the antenna driving module 120 may set an operation mode of the antenna array ATN_ARR to a transmission mode or a reception mode. However, for a more concise description, an embodiment in which the antenna driving module 120 drives the antenna array ATN_ARR in the transmission mode is described below as a representative example.

The antenna driving module 120 may include first to k-th antenna driving circuits 121 to 12k. The antenna driving module 120 may drive the antenna array ATN_ARR based on the first to k-th input signals TX1 to TXk. For example, the first to k-th antenna driving circuits 121 to 12k may respectively receive the first to k-th input signals TX1 to TXk, and respectively generate first to k-th amplified input signals TXA1 to TXAk. The first to k-th antenna driving circuits 121 to 12k may respectively provide the first to k-th amplified input signals TXA1 to TXAk to first to k-th antennas ATN1 to ATNk included in the antenna array ATN_ARR.

The antenna driving module 120 may detect power of the first to k-th amplified input signals TXA1 to TXAk. For example, the antenna driving module 120 may generate first to k-th detection power values PDET1 to PDETk respectively corresponding to power levels of the first to k-th amplified input signals TXA1 to TXAk. The antenna driving module 120 may provide the first to k-th detection power values PDET1 to PDETk to the communication power control module 130.

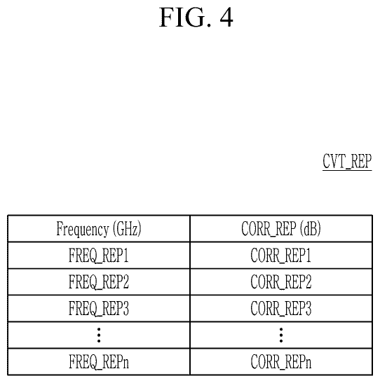

The communication power control module 130 may store a representative correction value table CVT_REP. The representative correction value table CVT_REP may include a plurality of representative correction values (hereinafter, referred to as “CORR_REP”) respectively corresponding to a plurality of different representative frequencies (hereinafter, referred to as “FREQ_REP”). A configuration of the representative correction value table CVT_REP is described in more detail below with reference to FIG. 4.

The communication power control module 130 may generate a target interpolation correction value (hereinafter, referred to as “CORR_INTP_target”) corresponding to a target frequency (hereinafter, referred to as “FREQ_target”) by interpolating the plurality of representative correction values CORR_REP included in the representative correction value table CVT_REP.

In an embodiment, a target frequency FREQ_target may refer to any one of ‘a frequency of the first to k-th input signals TX1 to TXk’, ‘a frequency at which the antenna driving module 120 operates’, or ‘a frequency of the signal output from the antenna array ATN_ARR’.

The communication power control module 130 may estimate total emission power PW_TEM output from the antenna array ATN_ARR based on the first to k-th detection power values PDET1 to PDETk. For example, the communication power control module 130 may estimate the total emission power PW_TEM by adding a target interpolation correction value (hereinafter, referred to as “CORR_INTP_target”) to the sum of the first to k-th detection power values PDET1 to PDETk.

The communication power control module 130 may control the operation of the antenna driving module 120 based on the estimated total emission power PW_TEM. For example, the communication power control module 130 may generate first to k-th gain control signals GCTRL1 to GCTRLK based on the estimated total emission power PW_TEM. The communication power control module 130 may provide first to k-th gain control signals GCTRL1 to GCTRLk respectively to the first to k-th antenna driving circuits 121 to 12k. In this case, each of the first to k-th antenna driving circuits 121 to 12k may adjust an amplification gain used to generate the amplified input signal TXA based on the input signal TX in response to the received gain control signal GCTRL. In this case, as the power levels of the first to k-th amplified input signals TXA1 to TXAk are adjusted, the magnitude of the total emission power PW_TEM may be adjusted.

In this way, the communication device 100 may appropriately adjust the magnitude of the total emission power PW_TEM. In this case, the magnitude of the total emission power PW_TEM may be large enough to prevent the communication failure between the base station BASE and the communication device 100 caused by the transmission loss of the uplink UL, and may be small enough to prevent the communication device 100 to consume unnecessary power.

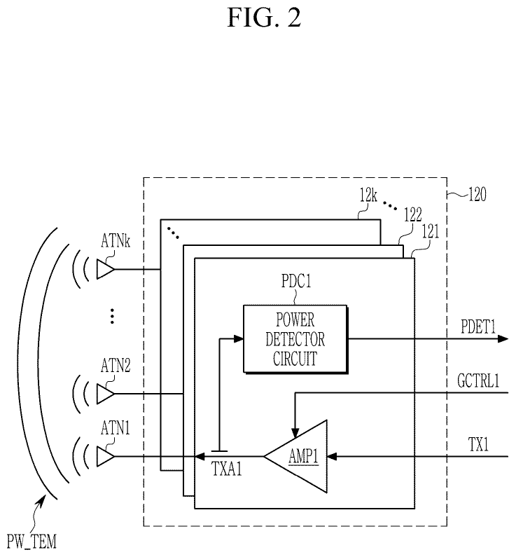

FIG. 2 is a block diagram showing a portion of the configuration shown in FIG. 1 in more detail. Referring to FIGS. 1 and 2, the antenna driving module 120 may include the first to k-th antenna driving circuits 121 to 12k. Hereinafter, for a more concise description, the configuration and operation of the first antenna driving circuit 121 will be representatively described.

The first antenna driving circuit 121 may include a first amplifier AMP1 and a first power detector circuit PDC1.

The first amplifier AMP1 may receive the first input signal TX1. The first amplifier AMP1 may generate the first amplified input signal TXA1 by amplifying the first input signal TX1. The first amplifier AMP1 may provide the first amplified input signal TXA1 to the first antenna ATN1.

In an embodiment, the first amplifier AMP1 may be implemented as a variable gain amplifier. For example, a gain of the first amplifier AMP1 may be adjusted in response to a first gain control signal GCTRL1.

For a more concise description, the first amplifier AMP1 is shown in FIG. 2 as directly receiving the first input signal TX1, however the scope of the present disclosure is not limited thereto. For example, the antenna driving module 120 may further include signal adjustment circuits of various types, such as a phase shifter, filter, attenuator, and/or modulator and the first amplifier AMP1 may be configured to receive the first input signal TX1 adjusted by the signal adjustment circuit.

The first power detector circuit PDC1 may measure the power of the first amplified input signal TXA1. The first power detector circuit PDC1 may generate the first detection power value PDET1 representing the power of the first amplified input signal TXA1.

For a more concise description, the configuration and operation of the first antenna driving circuit 121 has been representatively described with reference to FIG. 2, however the scope of the present disclosure is not limited thereto. For example, the second to k-th antenna driving circuits 122 to 12k may respectively include the second to k-th amplifiers AMP2 to AMPk and the second to k-th power detector circuits PDC2 to PDCk. In this case, the second to k-th antenna driving circuits 122 to 12k may respectively generate the second to k-th detection power values PDET2 to PDETk and receive the second to k-th gain control signals GCTRL2 to GCTRLK.

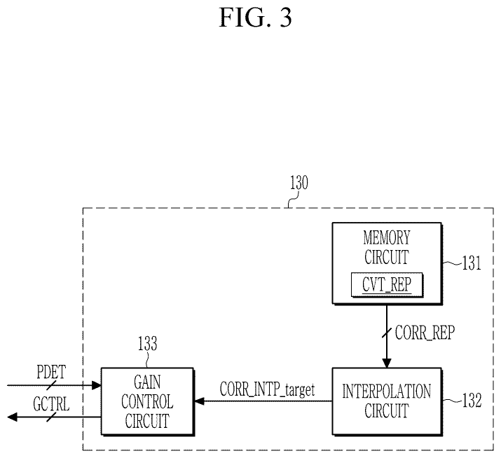

FIG. 3 is a block diagram showing a configuration of the communication power control module shown in FIG. 1 in more detail. Referring to FIGS. 1 to 3, the communication power control module 130 may include a memory circuit 131, an interpolation circuit 132, and a gain control circuit 133.

The memory circuit 131 may include the representative correction value table CVT_REP. The representative correction value table CVT_REP may include the plurality of representative correction values CORR_REP respectively corresponding to the plurality of representative frequencies FREQ_REP.

In an embodiment, the memory circuit 131 may be a one-time programmable (OTP) memory circuit.

The interpolation circuit 132 may read the plurality of representative correction values CORR_REP from the memory circuit 131. The interpolation circuit 132 may generate the target interpolation correction value CORR_INTP_target corresponding to the target frequency FREQ_target by interpolating between the plurality of representative correction values CORR_REP.

In an embodiment, the interpolation circuit 132 may generate the target interpolation correction value CORR_INTP_target corresponding to the target frequency by linearly interpolating the plurality of representative correction values CORR_REP. However, the scope of the present disclosure is not limited to a specific algorithm that the interpolation circuit 132 uses to generate the target interpolation correction value CORR_INTP_target.

The gain control circuit 133 may receive the plurality of detection power values PDET and the target interpolation correction value CORR_INTP_target. For example, the gain control circuit 133 may receive the first to k-th detection power values PDET1 to PDETk and the target interpolation correction value CORR_INTP_target.

The gain control circuit 133 may estimate the total emission power PW_TEM based on the first to k-th detection power values PDET1 to PDETk and the target interpolation correction value CORR_INTP_target. For example, the gain control circuit 133 may estimate the total emission power PW_TEM by adding the target interpolation correction value CORR_INTP_target to the sum of the first to k-th detection power values PDET1 to PDETk.

The gain control circuit 133 may generate the plurality of gain control signals GCTRL based on the estimated total emission power PW_TEM. For example, the gain control circuit 133 may generate the first to k-th gain control signals GCTRL1 to GCTRLk. The gain control circuit 133 may provide the first to k-th gain control signals GCTRL1 to GCTRLk respectively to the first to k-th amplifiers AMP1 to AMPk. In this case, as the gain of the first to k-th amplifiers AMP1 to AMPk are adjusted, the power levels of the first to k-th amplified input signals TXA1 to TXAk may be adjusted. Therefore, according to an embodiment of the present disclosure, the antenna array ATN_ARR may generate a signal having a power magnitude sufficient to enable the data to be normally transmitted to the base station BASE.

FIG. 4 is a drawing showing the representative correction value table shown in FIG. 1 in more detail. Referring to FIGS. 1 to 4, the memory circuit 131 may include the representative correction value table CVT_REP. The representative correction value table CVT_REP may include the plurality of representative correction values CORR_REP respectively corresponding to the plurality of representative frequencies FREQ_REP different each other. For example, the representative correction value table CVT_REP may include the first to n-th representative correction values CORR_REP1 to CORR_REPn. The first to n-th representative correction values CORR_REP1 to CORR_REPn may respectively correspond to the first to n-th representative frequencies FREQ_REP1 to FREQ_REPn.

In an embodiment, each frequency interval among the first to n-th representative frequencies FREQ_REP1 to FREQ_REPn may be nonuniform. In an embodiment, the first to n-th representative correction values CORR_REP1 to CORR_REPn may be calculated at a production stage of the communication device 100. Thus, the first to n-th representative correction values CORR_REP1 to CORR_REPn may be stored in the memory circuit 131 at the production stage of the communication device 100.

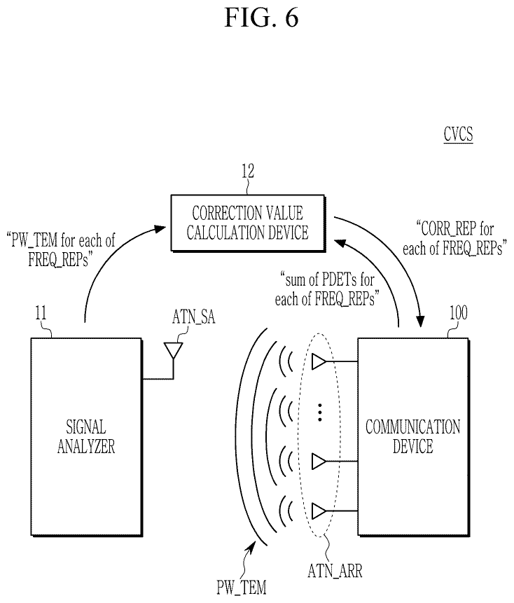

In an embodiment, each of the first to n-th representative correction values CORR_REP1 to CORR_REPn may represent a difference between the sum of the first to k-th detection power values PDET1 to PDETk and the total emission power PW_TEM in a case where the antenna array ATN_ARR is driven based on the first to k-th input signals TX1 to TXk having the corresponding representative frequency. In other words, each of the first to n-th representative correction values CORR_REP1 to CORR_REPn may represent the optimal correction value for a case where the antenna driving module 120 operates based on the corresponding representative frequency. A method for calculating the first to n-th representative correction values CORR_REP1 to CORR_REPn is described in more detail below with reference to FIG. 6.

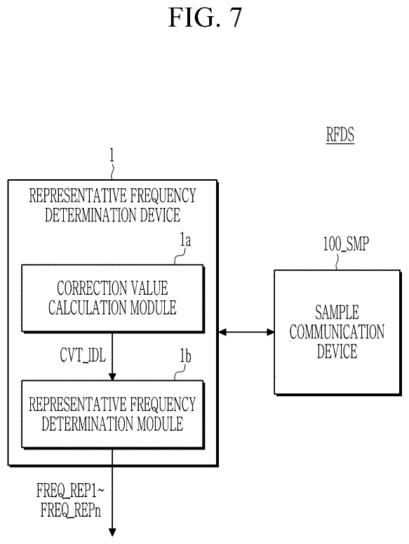

In an embodiment, each of the first to n-th representative frequencies FREQ_REP1 to FREQ_REPn may be included in a frequency band that the communication device 100 uses for the wireless communication. The first to n-th representative frequencies FREQ_REP1 to FREQ_REPn may be determined at a development stage of the communication device 100. A method for determining the first to n-th representative frequencies FREQ_REP1 to FREQ_REPn is described in more detail below with reference to FIGS. 7 to 11.

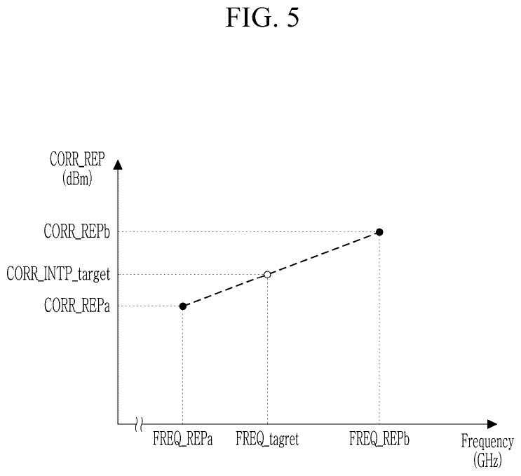

FIG. 5 is a drawing showing the operation of the interpolation circuit shown in FIG. 3 in more detail. Hereinafter, with reference to FIGS. 1 to 5, an embodiment in which the interpolation circuit 132 generates the target interpolation correction value CORR_INTP_target based on a linear interpolation algorithm will be representatively described.

The interpolation circuit 132 may read the plurality of representative correction values CORR_REP included in the representative correction value table CVT_REP from the memory circuit 131. For example, the interpolation circuit 132 may read representative correction values CORR_REPa and CORR_REPb respectively corresponding to two representative frequencies FREQ_REPa and FREQ_REPb adjacent to the target frequency FREQ_target among the first to n-th representative frequencies FREQ_REP1 to FREQ_REPn.

In an embodiment, one of the representative frequencies FREQ_REPa and FREQ_REPb may be less than the target frequency FREQ_target. The other one of the representative frequencies FREQ_REPa and FREQ_REPb may be greater than the target frequency FREQ_target. Hereinafter, for a more concise description, it may be assumed that the representative frequency FREQ_REPa is less than the target frequency FREQ_target, and the representative frequency FREQ_REPb is greater than the target frequency FREQ_target.

The interpolation circuit 132 may generate the interpolation correction value CORR_INTP_target by interpolating the representative correction values CORR_REPa and CORR_REPb. For example, the interpolation circuit 132 may calculate the target interpolation correction value CORR_INTP_target based on Equation 1 below.

$$COEE\_INTP \_target = CORR\_REPa + \frac{CORR\_REPb - CORR\_REPa}{FREQ\_REPb - FREQ\_REPa} \times ( FREQ\_target - FREQ\_REPa ) \qquad [ Equation 1 ]$$

In this way, the interpolation circuit 132 may generate the target interpolation correction value CORR_INTP_target corresponding to the target frequency FREQ_target at any target frequency between the frequencies FREQ_REPb and FREQ_REPa. In this case, the gain control circuit 133 may estimate the total emission power PW_TEM based on Equation 2 below.

$$PW\_TEM \approx CORR\_INTP \_target + \sum PDET \qquad [ Equation 2 ]$$

Referring to Equation 2, ΣPDET may represent the sum of the first to k-th detection power values PDET1 to PDETk. Thus, a correction value calculation device 12 (shown in FIG. 6) may estimate the total emission power PW_TEM based on the sum of the first to k-th detection power values PDET1 to PDETk and the target interpolation correction value CORR_INTP_target.

However, unlike the plurality of representative correction values CORR_REP included in the representative correction value table CVT_REP, the target interpolation correction value CORR_INTP_target may not be the optimal correction value for the case where the antenna driving module 120 operates based on the input signal TX having the target frequency FREQ_target. For example, if the antenna driving module 120 operates based on the target frequency FREQ_target, a summation of the target interpolation correction value CORR_INTP_target and the sum of the first to k-th detection power values PDET1 to PDETk may be different from the total emission power PW_TEM. In particular, when the plurality of representative frequencies FREQ_REP for the plurality of representative correction values CORR_REP included in the representative correction value table CVT_REP are not appropriately (non-optimally) selected, the summation of the target interpolation correction value CORR_INTP_target and the sum of the first to k-th detection power values PDET1 to PDETk may differ significantly from the total emission power PW_TEM. Some examples of non-optimal selection include: (i) when the plurality of representative frequencies FREQ_REP fail to appropriately represent a tendency of an optimal correction value as the frequency changes; and (ii) when the plurality of representative correction values CORR_REP, which respectively correspond to the plurality of representative frequencies FREQ_REP, correspond to an outlier that are far from the tendency of an optimal correction value as the frequency changes) Hereinafter, a method for determining the plurality of representative frequencies FREQ_REP which makes the summation of the target interpolation correction value CORR_INTP_target and the sum of the first to k-th detection power values PDET1 to PDETk closer to the total emission power PW_TEM will be described.

In an embodiment, the communication device 100 may estimate the total emission power PW_TEM more accurately when the plurality of representative frequencies FREQ_REP are determined according to an embodiment of the present disclosure. Therefore, according to the embodiment of the present disclosure, the total emission power PW_TEM may be accurately estimated even without individually estimating the emission power output from each of the first to k-th antennas ATN1 to ATNk.

FIG. 6 is a drawing showing an example of the correction value calculation system calculating the plurality of representative correction values shown in FIG. 4. Referring to FIGS. 1 to 6, a correction value calculation system CVCS may include a signal analyzer 11, the correction value calculation device 12, and the communication device 100. The correction value calculation system CVCS may operate at the production stage of the communication device 100.

During the production stage, RF power measurements on the communication device 100 may be performed at any representative frequency FREQ_REP. For example, the communication device 100 may drive the antenna array ATN_ARR based on the first representative frequency FREQ_REP1.

The communication device 100 may measure the power of signals input to the antenna array ATN_ARR while driving the antenna array ATN_ARR based on any representative frequency FREQ_REP. For example, the first to k-th power detector circuits PDC1 to PDCk may respectively generate the first to k-th detection power values PDET1 to PDETk while the communication device 100 drives the antenna array ATN_ARR based on the first representative frequency FREQ_REP1. The communication device 100 may provide the sum of the first to k-th detection power values PDET1 to PDETk to the correction value calculation device 12.

For a more concise description, hereinafter, an embodiment in which the communication device 100 provides the sum of the first to k-th detection power values PDET1 to PDETk to the correction value calculation device 12 will be representatively described. However, the scope of the present disclosure is not limited thereto. In another example the communication device 100 may provide the first to k-th detection power values PDET1 to PDETk to the correction value calculation device 12, and the correction value calculation device 12 may calculate the sum of the first to k-th detection power values PDET1 to PDETk.

The signal analyzer 11 may measure the total emission power PW_TEM from the antenna array ATN_ARR based on a signal analysis antenna ATN_SA. For example, the signal analyzer 11 may measure the total emission power PW_TEM from the antenna array ATN_ARR while the communication device 100 drives the antenna array ATN_ARR based on the first representative frequency FREQ_REP1. The signal analyzer 11 may provide the measured total emission power PW_TEM to the correction value calculation device 12.

The correction value calculation device 12 may calculate the representative correction value CORR_REP based on Equation 3 below.

$$CORR\_REP = PW\_TEM - \sum PDET \qquad [ Equation 3 ]$$

Referring to Equation 3, ΣPDET may represent the sum of the first to k-th detection power values PDET1 to PDETk. Thus, the correction value calculation device 12 may calculate the representative correction value CORR_REP based on the total emission power PW_TEM and the sum of the first to k-th detection power values PDET1 to PDETk. In this regard, it should be readily understood that the amount of RF power received by the signal analysis antenna ANT_SA depends on the distance between the signal analysis antenna ANT_SA and the antenna array ANT_ARR, as well as the characteristics of the signal analysis antenna ANT_SA and the antenna array ANT_ARR. Thus, the RF power received (“SAA_rcv”) by the signal analysis antenna ANT_SA may be an estimated fraction of the actual total emission power PW_TEM. Conversely, PW_TEM may be a scaled value of SAA_rcv, and normalized to ΣPDET such that an “apples to apples” comparison between PW_TEM and ΣPDET can be made to arrive at the correction value CORR_REP. Explained another way, the correction value CORR_REP may represent a normalized difference between the RF power received by the signal analysis antenna ANT_SA and ΣPDET.

For example, when the communication device 100 drives the antenna array ATN_ARR based on the first representative frequency FREQ_REP, the correction value calculation device 12 may calculate the first representative correction value CORR_REP1 by subtracting the sum of the first to k-th detection power values PDET1 to PDETk from the total emission power PW_TEM. Therefore, when the communication device 100 drives the antenna array ATN_ARR based on the first representative frequency FREQ_REP1, the communication device 100 may accurately estimate the total emission power PW_TEM based on the first representative correction value CORR_REP1 and the sum of the first to k-th detection power values PDET1 to PDETk.

In this way, the communication device 100 may operate based on each of the first to n-th representative frequencies FREQ_REP1 to FREQ_REPn; the signal analyzer 11 may measure the total emission power PW_TEM corresponding to each of the first to n-th representative frequencies FREQ_REP1 to FREQ_REPn; the communication device 100 may generate the sum of the first to k-th detection power values PDET1 to PDETk for each of the first to n-th representative frequencies FREQ_REP1 to FREQ_REPn; and the correction value calculation device 12 may calculate the first to n-th representative correction values CORR_REP1 to CORR_REPn.

Thus, each of the first to n-th representative correction values CORR_REP1 to CORR_REPn may be the optimal correction value for the case where the communication device 100 operates based on the corresponding representative frequency FREQ_REP. Therefore, if the communication device 100 drives the antenna array ATN_ARR based on one of the first to n-th representative correction values CORR_REP1 to CORR_REPn, the communication device 100 may accurately estimate the total emission power PW_TEM based on one of the first to n-th representative correction values CORR_REP1 to CORR_REPn.

When the plurality of representative frequencies FREQ_REP are determined according to an embodiment of the present disclosure, the communication device 100 may estimate the total emission power PW_TEM more accurately even without individually estimating the emission power output from each of the first to k-th antennas ATN1 to ATNk. As a result, the total emission power PW_TEM may be accurately estimated at a usage stage of the communication device 100 (i.e., communicating with the base station BASE) even without measuring (as in a conventional method) the correction value corresponding to one antenna ATN and one antenna driving circuit by driving only one of the antennas ATN included in the antenna array ATN_ARR. Therefore, according to an embodiment of the present disclosure, it is possible to significantly reduce the required time and cost at the production stage of the communication device 100.

FIG. 7 is a block diagram showing a representative frequency determination system for determining the plurality of representative frequencies shown in FIG. 4. Referring to FIGS. 1 to 7, a representative frequency determination system RFDS may include a representative frequency determination device 1 and a sample communication device 100_SMP. The representative frequency determination system RFDS may operate at the development stage of the communication device 100 before its production stage.

The sample communication device 100_SMP may be configured to correspond to the communication device 100. For example, the sample communication device 100_SMP may have the same configuration as the communication device 100 and may be manufactured through the same process. However, the scope of the present disclosure is not limited thereto, and the sample communication device 100_SMP may also include an antenna driving module having the same configuration as the antenna driving module 120 and produced through the same process

The representative frequency determination device 1 may generate the first to n-th representative frequencies FREQ_REP1 to FREQ_REPn based on a frequency feature of the sample communication device 100_SMP. Hereinafter, the configuration and operation of the representative frequency determination device 1 will be described in more detail.

The representative frequency determination device 1 may include a correction value calculation module 1a and a representative frequency determination module 1b.

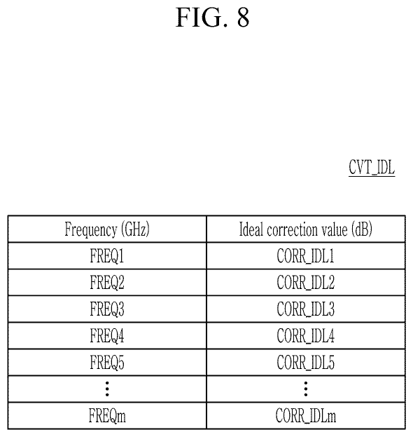

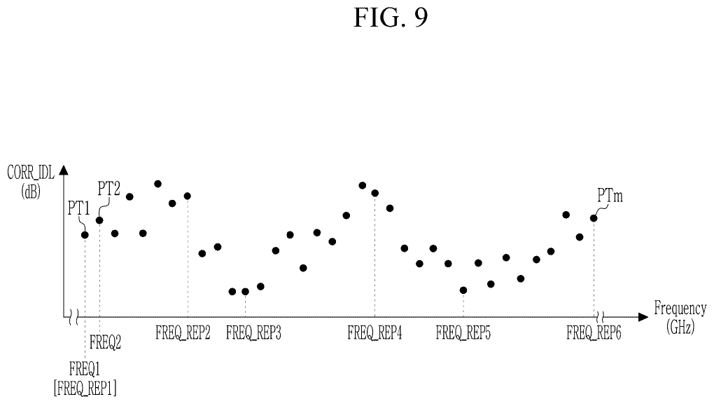

Using a similar method to the correction value calculation device 12 described with reference to FIG. 6 above, the correction value calculation module 1a may calculate an ideal correction value (hereinafter, referred to as “CORR_IDL”) for each case where the sample communication device 100_SMP operates based on each of the plurality of frequencies included in the frequency band used for communication with the base station BASE. For example, the correction value calculation circuit (“module”) 1a may generate an ideal correction value table CVT_IDL for the sample communication device 100_SMP. In this case, the ideal correction value table CVT_IDL may include the plurality of ideal correction values CORR_IDL respectively corresponding to the plurality of frequencies included in the frequency band that the sample communication device 100_SMP uses for the communication. The operation of the correction value calculation module 1a will be described in more detail below with reference to FIGS. 8 and 9.

The representative frequency determination circuit (“module”) 1b may be a processing device including a processor executing instructions read from a memory to carry out the operations described herein. To this end, the module 1b may determine the first to n-th representative frequencies FREQ_REP1 to FREQ_REPn based on the ideal correction value table CVT_IDL. For example, the representative frequency determination module 1b may determine some of the plurality of frequencies included in the frequency band used by the sample communication device 100_SMP for the base station communication, as the first to n-th representative frequencies FREQ_REP1 to FREQ_REPn based on the plurality of ideal correction values CORR_IDL included in the ideal correction value table CVT_IDL. The operation of the representative frequency determination module 1b will be described in more detail below with reference to FIGS. 9 to 11.

FIG. 8 is a drawing showing the ideal correction value table shown in FIG. 7 in more detail. Referring to FIGS. 1 to 8, the ideal correction value table CVT_IDL may include first to m-th ideal correction values CORR_IDL1 to CORR_IDLm. The first to m-th ideal correction values CORR_IDL1 to CORR_IDLm may respectively correspond to first to m-th frequencies FREQ1 to FREQm. That is, the correction value calculation module 1a may individually calculate the optimal correction value for each case where the sample communication device 100_SMP operates based on each of the first to m-th frequencies FREQ1 to FREQm.

For a more detailed example, the correction value calculation module 1a may calculate the i-th ideal correction value CORR_IDLi (here, i indicates an integer greater than or equal to 1 and less than or equal to m) by a method similar to that described above with reference to FIG. 6. In this case, the i-th ideal correction value CORR_IDLi may represent the optimal correction value for estimating the total emission power PW_TEM for a case where the sample communication device 100_SMP operates based on the i-th frequency FREQi. For example, the i-th ideal correction value CORR_IDLi may correspond to a value acquired by subtracting the sum of the first to k-th detection power values PDET1 to PDETk from the total emission power PW_TEM in the case where the sample communication device 100_SMP operates based on the i-th frequency FREQi.

In an embodiment, the first to m-th frequencies FREQ1 to FREQm may be included in the frequency band that the sample communication device 100_SMP is designed to use for communication with the base station. For example, the first to m-th frequencies FREQ1 to FREQm may be the frequencies that divide the frequency band that the sample communication device 100_SMP uses for the communication into uniform intervals. However, the scope of the present disclosure is not limited thereto, and the first to m-th frequencies FREQ1 to FREQm may be any different frequencies included in the frequency band that the sample communication device 100_SMP uses for the communication.

Hereinafter, for a more concise description, it will be assumed that the first to m-th frequencies FREQ1 to FREQm forms an increasing arithmetic sequence. However, the scope of the present disclosure is not limited thereto.

FIG. 9 is a graph showing an example of the plurality of ideal correction values shown in FIG. 8. In FIG. 9, a horizontal axis may represent the frequency, and a vertical axis may represent the ideal correction value CORR_IDL.

Referring to FIGS. 1 to 9, each of the first to m-th ideal correction values CORR_IDL1 to CORR_IDLm may be shown as a point PT. For example, the first ideal correction value CORR_IDL1 is shown as the first point PT1, the second ideal correction value CORR_IDL2 is shown as the second point PT2, the last ideal correction value is shown as a last point PTm, and the other points are not labeled for clarity of illustration.

The first to m-th points PT1 to PTm may respectively correspond to the first to m-th frequencies FREQ1 to FREQm. That is, the first to m-th ideal correction values CORR_IDL1 to CORR_IDLm may respectively correspond to the first to m-th frequencies FREQ1 to FREQm.

The representative frequency determination module 1b may determine some of the first to m-th frequencies FREQ1 to FREQm as the representative frequencies FREQ_REP. For example, the representative frequency determination module 1b may select, as the representative frequencies FREQ_REP, the plurality of frequencies FREQ that appropriately represent a tendency between the frequency FREQ and the ideal correction value CORR_IDL (i.e., have the representativeness of a relationship between the frequency FREQ and the ideal correction value CORR_IDL) from among the first to m-th frequencies FREQ1 to FREQm.

For a more detailed example, the representative frequency determination module 1b may determine the first to n-th representative frequencies FREQ_REP1 to FREQ_REPn, so that errors between corresponding ones of the first to m-th ideal correction values CORR_IDL1 to CORR_IDLm and the first to m-th interpolation correction values (hereinafter, referred to as “CORR_INTP”) generated by linearly interpolating the ideal correction values corresponding to the first to n-th representative frequencies FREQ_REP1 to FREQ_REPn are less than a predetermined threshold error. For example, the representative frequency determination module 1b may determine the first to n-th representative frequencies FREQ_REP1 to FREQ_REPn based on various type of sample analysis algorithms, such as segmented linear regression analysis.

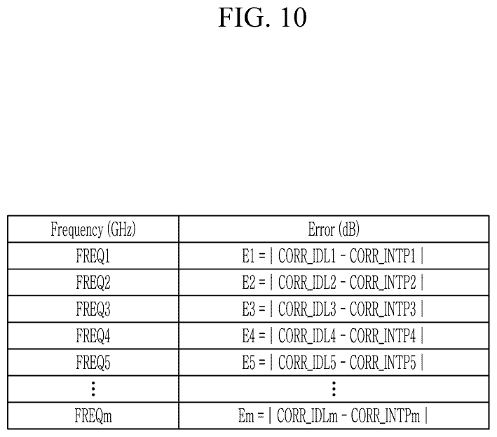

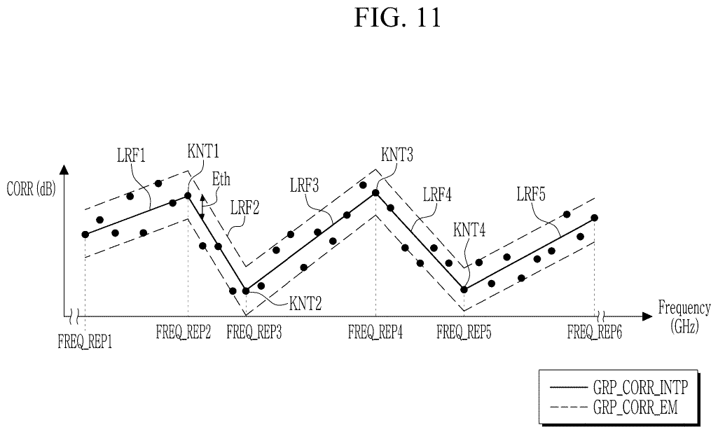

Accordingly, if the first to n-th representative frequencies FREQ_REP1 to FREQ_REPn are determined according to the embodiment of the present disclosure, a difference between i) ‘the interpolation correction value corresponding to any frequency wherein the interpolation correction value is generated by linearly interpolating between the ideal correction values’, and ii) ‘the ideal correction value corresponding to the frequency’ may be less than the threshold error. In designing embodiments, a specific number of representative frequencies may also be considered. Embodiments with a relatively high number of representative frequencies may have a higher cost of production. The relationship between the interpolation correction value and the ideal correction value will be described in more detail below with reference to FIGS. 10 and 11.

In this way, the representative frequency determination module 1b may determine the first frequency FREQ1 as the first representative frequency FREQ_REP1. In a similar way, the representative frequency determination module 1b may determine the second to sixth representative frequencies FREQ_REP2 to FREQ_REP6 from the first to m-th frequencies FREQ1 to FREQm. For a more concise description, the first to sixth representative frequencies FREQ_REP1 to FREQ_REP6 are shown representatively in FIG. 9. However, the scope of the present disclosure is not limited to the number of representative frequencies FREQ_REP determined by the representative frequency determination module 1b. For example, the representative frequency determination module 1b may determine fewer than six (e.g., two or three) representative frequencies from the first to m-th frequencies FREQ1 to FREQm, or determine more than six (e.g., eight or ten) representative frequencies. That is, “n” may be an integer less or greater than 6.

In an embodiment, the representative frequency determination module 1b may determine the maximum and minimum frequencies among the first to m-th frequencies FREQ1 to FREQm as at least two of the representative frequencies. For example, the representative frequency determination module 1b may determine the first and m-th frequencies FREQ1 and FREQm as the representative frequencies. In this case, the first and m-th frequencies FREQ1 and FREQm may be determined even without considering the first to m-th ideal correction values CORR_IDL1 to CORR_IDLm, thus reducing a calculation amount of the representative frequency determination module 1b.

FIGS. 10 and 11 are diagrams showing the relationship between the interpolation correction values generated by linearly interpolating the ideal correction values corresponding to the representative frequencies and the ideal correction values, shown in FIG. 9.

First, referring to FIGS. 1 to 10, the first to m-th interpolation correction values CORR_INTP1 to CORR_INTPm may respectively correspond to the first to m-th frequencies FREQ1 to FREQm. The first to m-th interpolation correction values CORR_INTP1 to CORR_INTPm may each correspond to results of linearly interpolating between adjacent ones of the ideal correction values CORR_IDL corresponding to the first to n-th representative frequencies FREQ_REP1 to FREQ_REPn. For example, the i-th interpolation correction value CORR_INTPi (wherein, i is an integer greater than or equal to 1 and less than or equal to m) may correspond to the result of linearly interpolating between two representative frequencies adjacent to the i-th frequency FREQi among the first to n-th representative frequencies FREQ_REP1 to FREQ_REPn. In more detail, the i-th interpolation correction value CORR_INTPi may correspond to Equation 4 below.

$$CORR\_INTPi = CORR\_IDLa + \frac{CORR\_IDLb - CORR\_IDLa}{FREQ\_REPb - FREQ\_REPa} \times ( FREQi\_FREQ \_REPa ) \qquad [ Equation 4 ]$$

Referring to Equation 4, FREQ_REPa and FREQ_REPb may represent the two representative frequencies adjacent to the i-th frequency FREQi, and CORR_IDLa and CORR_IDLb may represent the ideal frequencies respectively corresponding to FREQ_REPa and FREQ_REPb. In this case, FREQ_REPa may be less than the i-th frequency FREQi, and FREQ_REPb may be greater than the i-th frequency FREQi.

First to m-th errors E1 to Em may respectively correspond to differences between the first to m-th interpolation correction values CORR_INTP1 to CORR_INTPm and the first to m-th ideal correction values CORR_IDL1 to CORR_IDLm. For example, the first error E1 may represent the difference between the first interpolation correction value CORR_INTP1 and the first ideal correction value CORR_IDL1, and the second error E2 may represent the difference between the second interpolation correction value CORR_INTP2 and the second ideal correction value CORR_IDL2.

The representative frequency determination module 1b may determine the first to n-th representative frequencies FREQ_REP1 to FREQ_REPn, which make each of the first to m-th errors E1 to Em less than or equal to the threshold error. That is, the representative frequency determination module 1b may determine the first to n-th representative frequencies FREQ_REP1 to FREQ_REPn, so that the first to m-th errors E1 to Em are small enough (e.g., to be less than or equal to the threshold error). For example, the representative frequency determination module 1b may perform segmented linear regression analysis. The representative frequency determination module 1b may determine the plurality of representative frequencies FREQ_REP based on a plurality of linear regression functions generated by the segmented linear regression analysis.

Hereinafter, a method for determining the plurality of representative frequencies FREQ_REP by the representative frequency determination module 1b based on the segmented linear regression analysis will be described in more detail with further reference to FIG. 11. In FIG. 11, a horizontal axis may represent the frequency, and a vertical axis may represent the correction value.

The representative frequency determination module 1b may generate a plurality of linear regression functions by performing the segmented linear regression analysis on the first to m-th ideal correction values CORR_IDL1 to CORR_IDLm (or the first to m-th points PT1 to PTm) respectively corresponding to the first to m-th frequencies FREQ1 to FREQm. For example, the representative frequency determination module 1b may generate the first to fifth linear regression functions LRF1 to LRF5.

For a more concise description, FIG. 11 representatively shows an embodiment in which the representative frequency determination module 1b generates five linear regression functions. However, the scope of the present disclosure is not limited to the number of linear regression functions generated by the representative frequency determination module 1b. For example, the representative frequency determination module 1b may generate five or fewer linear regression functions, or may generate five or more linear regression functions, depending on a design goal.

Intersections of the first to fifth linear regression functions LRF1 to LRF5 may be referred to as knot points KNT. For example, the intersection of the first and second linear regression functions LRF1 and LRF2 may be referred to as the first knot point KNT1; the intersection of the second and third linear regression functions LRF2 and LRF3 may be referred to as the second knot point KNT2; the intersection of the third and fourth linear regression functions LRF3 and LRF4 may be referred to as the third knot point KNT3; and the intersection of the fourth and fifth linear regression functions LRF4 and LRF5 may be referred to as the fourth knot point KNT4.

The representative frequency determination module 1b may determine each of the plurality of knot points KNT as the representative frequency. For example, the representative frequency determination module 1b may determine the first to fourth knot points KNT1 to KNT4 as the second to fifth representative frequencies FREQ_REP2 to FREQ_REP5, respectively.

In an embodiment, the frequency corresponding to the knot point KNT may also be referred to as a knot frequency. For example, each of the second to fifth representative frequencies FREQ_REP2 to FREQ_REP5 may also be referred to as the knot frequency.

In an embodiment, each of the plurality of knot frequencies may be one of the first to m-th frequencies FREQ1 to FREQm. In other words, each of the plurality of knot points KNT may correspond to one of the frequencies, and may correspond to the ideal correction value CORR_IDL corresponding to the frequency.

In an embodiment, the representative frequency determination module 1b may determine a loss function of the segmented linear regression analysis, which makes each of the first to m-th errors E1 to Em less than a threshold error Eth. The representative frequency determination module 1b may generate the first to fifth linear regression functions LRF1 to LRF5 based on the determined loss function.

Hereinafter, for a more concise description, an embodiment in which the representative frequency determination module 1b determines the maximum and minimum values among the first to m-th frequencies FREQ1 to FREQm as the representative frequencies will be described. For example, the representative frequency determination module 1b may determine the first frequency FREQ1 as the first representative frequency FREQ_REP1. However, the scope of the present disclosure is not limited thereto.

Results of linearly interpolating the ideal correction values corresponding to the plurality of representative frequencies FREQ_REP may be shown as an interpolation correction value graph GRP_CORR_INTP. In this case, the interpolation correction value graph GRP_CORR_INTP may be implemented as a combination of the first to fifth linear regression functions LRF1 to LRF5. For example, the interpolation correction value graph GRP_CORR_INTP may correspond to a connection of the points representing the ideal correction values respectively corresponding to the plurality of representative frequencies.

Values greater or less than the interpolation correction value graph GRP_CORR_INTP by the threshold error Eth may be shown in a correction value error margin graph GRP_CORR_EM. In this case, all the points (for example, the first to m-th points PT1 to PTm) for the first to m-th ideal correction values CORR_IDL1 to CORR_IDLm respectively corresponding to the first to m-th frequencies FREQ1 to FREQm may be included between the interpolation correction value graphs GRP_CORR_INTP. That is, the first to m-th points PT1 to PTm may be included in a region having boundaries indicated by dotted lines.

Therefore, according to an embodiment of the present disclosure, the first to n-th representative frequencies FREQ_REP1 to FREQ_REPn may be determined so that the error between the ideal correction value and each of the interpolation correction values generated based on the first to n-th representative frequencies FREQ_REP1 to FREQ_REPn is less than the threshold error Eth.

For a more concise description, with referring FIG. 11, an embodiment in which the representative frequency determination module 1b determine the first to n-th representative frequencies FREQ_REP1 to FREQ_REPn based on the segmented linear regression analysis has been described. However the scope of the present disclosure is not limited thereto. For example, the representative frequency determination module 1b may also determine the first to n-th representative frequencies FREQ_REP1 to FREQ_REPn based on any type of machine learning algorithm.

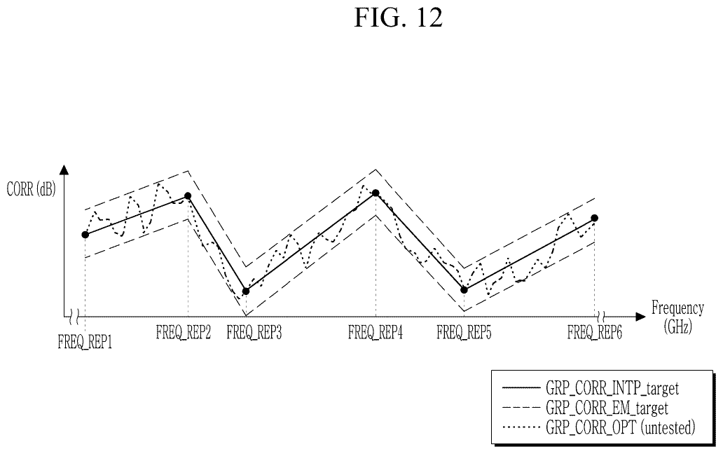

FIG. 12 is a drawing showing the target interpolation correction value generated based on the determined representative frequency according to an embodiment of the present disclosure. In FIG. 12, a horizontal axis may represent the frequency, and a vertical axis may represent the correction value.

Referring to FIGS. 1 to 6 and 12, the first to n-th representative correction values CORR_REP1 to CORR_REPn respectively corresponding to the first to n-th representative frequencies FREQ_REP1 to FREQ_REPn may be measured at the production stage of the communication device 100. (In this case, due to process deviation occurring in the communication device 100 and the sample communication device 100_SMP, the first to n-th representative correction values CORR_REP1 to CORR_REPn may have magnitudes similar to but different from the ideal correction values corresponding to the representative frequencies described above with reference to FIGS. 7 to 11).

The first to n-th representative correction values CORR_REP1 to CORR_REPn corresponding to the first to n-th representative frequencies FREQ_REP1 to FREQ_REPn may be shown as points in FIG. 12. In this case, according to the target frequency FREQ_target, the interpolation circuit 132 may generate the target interpolation correction value CORR_INTP_target by interpolating the first to n-th representative correction values CORR_REP1 to CORR_REPn.

The target interpolation correction value CORR_INTP_target according to the magnitude of the target frequency FREQ_target may be shown in a target interpolation correction value graph GRP_CORR_INTP_target.

Values greater or less than the target interpolation correction values CORR_INTP_target corresponding to any target frequencies FREQ_target by the threshold error Eth may be shown in a target error margin graph GRP_CORR_EM_target.

The optimal correction value when the communication device 100 operates at any target frequency FREQ_target may be shown in an optimal correction value graph GRP_CORR_OPT. At the production stage of the communication device 100, the optimal correction values corresponding to the optimal correction value graph GRP_CORR_OPT may be unmeasured, and only the first to n-th representative correction values CORR_REP1 to CORR_REPn corresponding to the first to n-th representative frequencies FREQ_REP1 to FREQ_REPn may be measured.

The communication device 100 and the sample communication device 100_SMP may have the same configuration and may be produced through the same process. Therefore, if the first to n-th representative frequencies FREQ_REP1 to FREQ_REPn are determined based on the sample communication device 100_SMP, the target interpolation correction value CORR_INTP_target calculated based on any target frequency FREQ_target may have a magnitude almost equal to the unmeasured optimal correction value even if the process deviation occurring in the communication device 100 and the sample communication device 100_SMP.

In other words, the optimal correction value graph GRP_CORR_OPT may be disposed between the target error margin graphs GRP_CORR_EM_target. Alternatively, the optimal correction value graph GRP_CORR_OPT may not deviate significantly from the target error margin graph GRP_CORR_EM_target, even if the deviation occurs.

That is, according to the embodiment of the present disclosure, when the first to n-th representative frequencies FREQ_REP1 to FREQ_REPn are determined and the target interpolation correction value CORR_INTP_target is calculated based on the first to n-th representative frequencies FREQ_REP1 to FREQ_REPn, the target interpolation correction value CORR_INTP_target may have a magnitude close to the optimal correction value. In this case, the communication device 100 may accurately measure the total emission power PW_TEM based on the target interpolation correction value CORR_INTP_target. Therefore, the communication device 100 may adjust the power of the input signal provided to the antenna array ATN_ARR to the optimal power level.

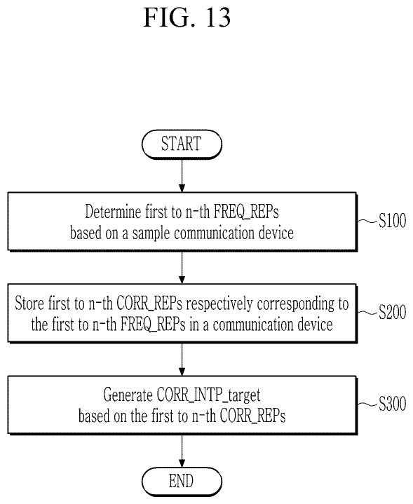

FIG. 13 is a drawing showing a control method of a communication device according to an embodiment of the present disclosure. Referring to FIGS. 1 to 13, at operation S100, the representative frequency determination device 1 may determine the first to n-th representative frequencies FREQ_REP1 to FREQ_REPn based on the sample communication device 100_SMP. For example, at the development stage of the communication device 100, the representative frequency determination device 1 may determine the first to n-th representative frequencies FREQ_REP1 to FREQ_REPn based on the sample communication device 100_SMP.

At operation S200, the correction value calculation device 12 may store, in the communication device 100, the first to n-th representative correction values CORR_REP1 to CORR_REPn respectively corresponding to the first to n-th representative frequencies FREQ_REP1 to FREQ_REPn. For example, at the production stage of the communication device 100, the correction value calculation device 12 may store, in the memory circuit 131, the first to n-th representative correction values CORR_REP1 to CORR_REPn for the communication device 100.

At operation S300, the communication device 100 may generate the target interpolation correction value CORR_INTP_target based on the first to n-th representative correction values CORR_REP1 to CORR_REPn. For example, at the usage stage of the communication device 100, the communication power control module 130 may generate the target interpolation correction value CORR_INTP_target by linearly interpolating the first to n-th representative correction values CORR_REP1 to CORR_REPn. In this case, the communication power control module 130 may accurately estimate the total emission power PW_TEM from the antenna array ATN_ARR based on the target interpolation correction value CORR_INTP_target, and may appropriately control the gain of the amplifier AMP based thereon.

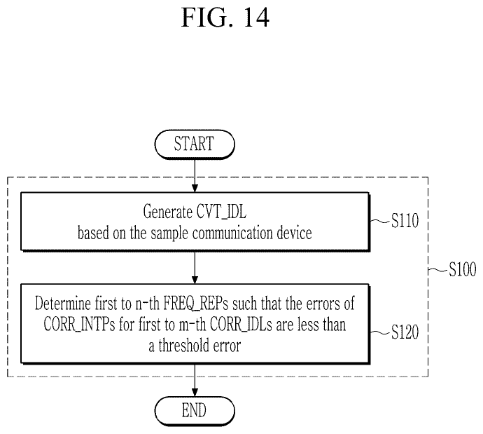

FIG. 14 is a drawing showing operation S100 shown in FIG. 13 in more detail. Referring to FIGS. 1 to 14, operation S100 may include operations S110 and S120 described below.

At operation S110, the representative frequency determination device 1 may generate the ideal correction value table CVT_IDL based on the sample communication device 100_SMP. For example, the correction value calculation module 1a may measure the first to m-th ideal correction values CORR_IDL1 to CORR_IDLm respectively corresponding to the first to m-th frequencies FREQ1 to FREQm.

At operation S120, the representative frequency determination device 1 may determine the first to n-th representative frequencies FREQ_REP1 to FREQ_REPn such that the errors of the plurality of interpolation correction values CORR_INTP for the first to m-th ideal correction values CORR_IDL1 to CORR_IDLm are less than the threshold error Eth. In this case, the plurality of interpolation correction values CORR_INTP may correspond to results of interpolating the ideal correction values CORR_IDL corresponding to the first to n-th representative frequencies FREQ_REP1 to FREQ_REPn. For example, by performing the segmented linear regression analysis, the representative frequency determination device 1 may determine the first to n-th representative frequencies FREQ_REP1 to FREQ_REPn allowing the first to m-th errors E1 to Em, respectively corresponding to the first to m-th interpolation correction values CORR_INTP1 to CORR_INTPm and the first to m-th ideal correction values CORR_IDL1 to CORR_IDLm, to be less than the threshold error Eth.

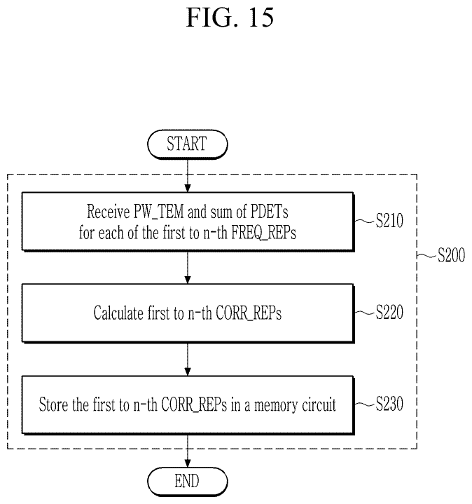

FIG. 15 is a drawing showing operation S200 shown in FIG. 13 in more detail. Referring to FIGS. 1 to 15, operation S200 may include operations S210 to S230 described below.

At operation S210, the correction value calculation device 12 may receive the total emission power PW_TEM and the sum of the first to k-th detection power values PDET1 to PDETk for each of the first to n-th representative frequencies FREQ_REP1 to FREQ_REPn. For example, when the communication device 100 drives the antenna array ATN_ARR based on the first representative frequency FREQ_REP1, the correction value calculation device 12 may receive the sum of the first to k-th detection power values PDET1 to PDETk for the first representative frequency FREQ_REP1 from the communication device 100, and receive the total emission power PW_TEM for the first representative frequency FREQ_REP1 from the signal analyzer 11. In this way, the correction value calculation device 12 may receive the total emission power PW_TEM and the sum of the first to k-th detection power values PDET1 to PDETk for each of the first to n-th representative frequencies FREQ_REP1 to FREQ_REPn.

At operation S220, the correction value calculation device 12 may calculate the first to n-th representative correction values CORR_REP1 to CORR_REPn. For example, the correction value calculation device 12 may calculate the first representative correction value CORR_REP1 based on the sum of the first to k-th detection power values PDET1 to PDETk and the total emission power PW_TEM corresponding to the first representative frequency FREQ_REP1. Similarly, the correction value calculation device 12 may calculate the second representative correction value CORR_REP2 based on the sum of the first to k-th detection power values PDET1 to PDETk and the total emission power PW_TEM corresponding to the second representative frequency FREQ_REP2. In this way, the correction value calculation device 12 may sequentially calculate the first to n-th representative correction values CORR_REP1 to CORR_REPn.

For a more concise description, FIG. 15 shows an embodiment in which operation S220 is performed after operation S210, however the scope of the present disclosure is not limited thereto. For example, operations S210 and S220 may be performed simultaneously. For a more detailed example, the correction value calculation device 12 may be configured to calculate the corresponding representative correction value CORR_REP whenever receiving a pair of “the total emission power PW_TEM and the sum of the first to k-th detection power values PDET1 to PDETk” corresponding to one representative frequency FREQ_REP.

At operation S230, the correction value calculation device 12 may store, in the memory circuit 131, the first to n-th representative correction values CORR_REP1 to CORR_REPn. That is, the correction value calculation device 12 may store the representative correction value table CVT_REP in the memory circuit 131.

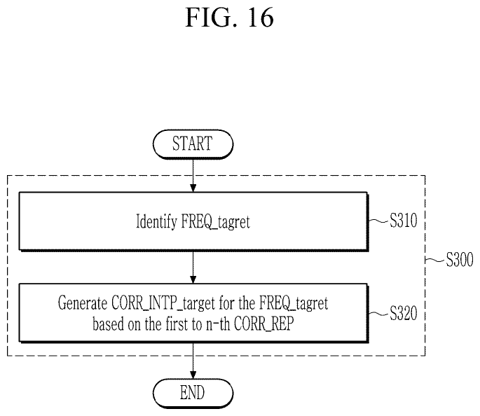

FIG. 16 is a drawing showing operation S300 shown in FIG. 13 in more detail. Referring to FIGS. 1 to 16, operation S300 may include operations S310 and S320 described below.

At operation S310, the communication device 100 may identify the target frequency FREQ_target. For example, the communication device 100 may identify the frequency of the signal to be transmitted from the antenna array ATN_ARR.

At operation S320, the communication device 100 may generate the target interpolation correction value CORR_INTP_target based on the first to n-th representative correction values CORR_REP1 to CORR_REPn. For example, the interpolation circuit 132 may read the two representative correction values CORR_REPa and CORR_REPb included in the representative correction value table CVT_REP from the memory circuit 131. The interpolation circuit 132 may generate the target interpolation correction value CORR_INTP_target by linearly interpolating the read representative correction values CORR_REPa and CORR_REPb.

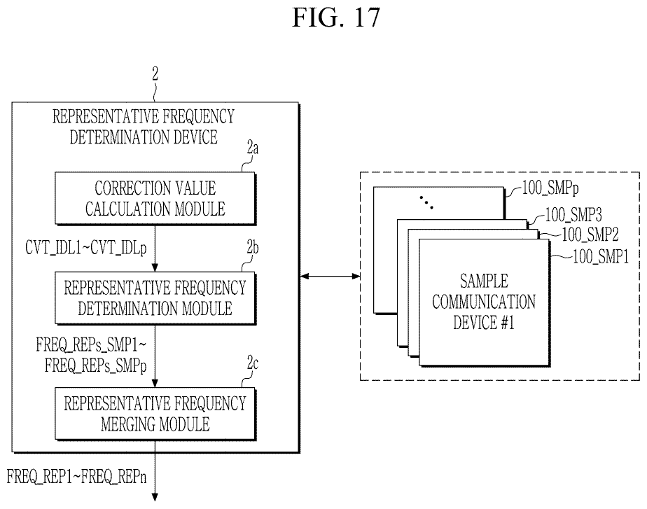

FIG. 17 is a block diagram showing the representative frequency determination system for determining the plurality of representative frequencies shown in FIG. 4 according to an embodiment. Referring to FIGS. 1 to 5 and 17, the representative frequency determination system RFDS may include a representative frequency determination device 2 and first to p-th sample communication devices 100_SMP1 to 100_SMPp. The representative frequency determination system RFDS may operate at the development stage of the communication device 100 before its production stage.

Each of the first to p-th sample communication devices 100_SMP1 to 100_SMPp may be configured to correspond to the communication device 100. For example, each of the first to p-the sample communication devices 100_SMP1 to 100_SMPp may have the same configuration as the communication device 100 and may be produced through the same process.

The representative frequency determination device 2 may generate the first to n-th representative frequencies FREQ_REP1 to FREQ_REPn based on the frequency features of the first to p-th sample communication devices 100_SMP1 to 100_SMPp. Hereinafter, the configuration and operation of the representative frequency determination device 2 will be described in more detail.

The representative frequency determination device 2 may include a correction value calculation module 2a, a representative frequency determination module 2b, and a representative frequency merging module 2c.

The correction value calculation module 2a may generate the first to p-th ideal correction value tables CVT_IDL1 to CVT_IDLp respectively for the first to p-th sample communication devices 100_SMP1 to 100_SMPp. In this case, the first ideal correction value table CVT_IDL1 may include the plurality of ideal correction values CORR_IDL respectively corresponding to cases where the first sample communication device 100_SMP1 operates based on the first to m-th frequencies FREQ1 to FREQm; and the second ideal correction value table CVT_IDL2 may include the plurality of ideal correction values CORR_IDL respectively corresponding to cases where the second sample communication device 100_SMP2 operates based on the first to m-th frequencies FREQ1 to FREQm. Since an operation method of the correction value calculation module 2a generating each of the first to p-th ideal correction value tables CVT_IDL1 to CVT_IDLp is similar to the operation method of the correction value calculation module 1a generating the ideal correction value table CVT_IDL described above, thus detailed description will be omitted.

The representative frequency determination module 2b may generate first to p-th plurality of representative frequencies FREQ_REPs_SMP1 to FREQ_REPs_SMPp, based on the first to p-th ideal correction value tables CVT_IDL1 to CVT_IDLp, respectively. For example, the representative frequency determination module 2b may generate the first plurality of representative frequencies FREQ_REPs_SMP1 based on the first ideal correction value table CVT_IDL1. For a more detailed example, the representative frequency determination module 2b may generate the first plurality of representative frequencies FREQ_REPs_SMP1 based on the first ideal correction value table CVT_IDL1 by using a method similar to that used for the operation of the representative frequency determination module 1b generating the first to n-th representative frequencies FREQ_REP1 to FREQ_REPn based on the ideal correction value table CVT_IDL described above with reference to FIGS. 7 to 11. In this way, the representative frequency determination module 2b may generate the first to p-th plurality of representative frequencies FREQ_REPs_SMP1 to FREQ_REPs_SMPp respectively based on the first to p-th ideal correction value tables CVT_IDL1 to CVT_IDLp.

The representative frequency merging module 2c may generate the first to n-th representative frequencies FREQ_REP1 to FREQ_REPn based on the first to p-th plurality of representative frequencies FREQ_REPs_SMP1 to FREQ_REPs_SMPp. For example, the representative frequency merging module 2c may determine the top “n” representative frequencies each of which has the largest number among the first to p-th plurality of representative frequencies FREQ_REPs_SMP1 to FREQ_REPs_SMPp as first to n-th representative frequencies FREQ_REP1 to FREQ_REPn. For example, the representative frequency merging module 2c may determine the first frequency FREQ1 as the representative frequency FREQ_REP when the representative frequency corresponding to the first frequency FREQ1 has the largest number (for example, “p” representative frequencies) among the first to p-th plurality of representative frequencies FREQ_REPs_SMP1 to FREQ_REPs_SMPp; and the representative frequency merging module 2c may determine the eighth frequency FREQ8 as the representative frequency FREQ_REP when the representative frequency corresponding to the eighth frequency FREQ8 has the n-th largest number among the first to p-th plurality of representative frequencies FREQ_REPs_SMP1 to FREQ_REPs_SMPp.

For a more concise description, an embodiment in which the representative frequency merging module 2c generates each of the first to n-th representative frequencies FREQ_REP1 to FREQ_REPn based on number of the frequencies included on the first to p-th plurality of representative frequencies FREQ_REPs_SMP1 to FREQ_REPs_SMPp has been representatively described. However, the scope of the present disclosure is not limited thereto. For example, the representative frequency merging module 2c may generate each of the first to n-th representative frequencies FREQ_REP1 to FREQ_REPn based on average of the representative frequencies that have similar magnitudes among the first to p-th plurality of representative frequencies FREQ_REPs_SMP1 to FREQ_REPs_SMPp. That is, the scope of the present disclosure is not limited to a specific algorithm by which the representative frequency merging module 2c generates the first to n-th representative frequencies FREQ_REP1 to FREQ_REPn.

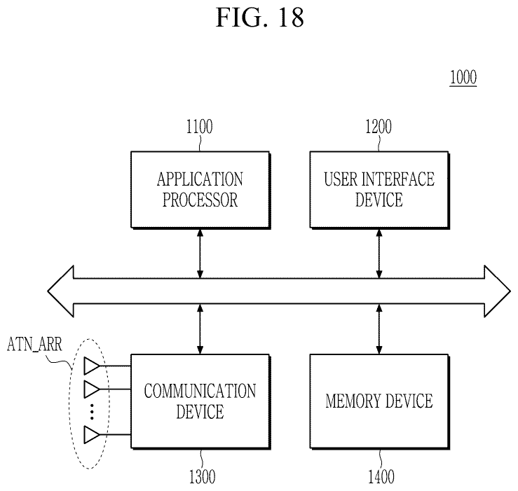

FIG. 18 is a block diagram showing a more detailed configuration of an electronic device according to an embodiment. Referring to FIGS. 1 to 18, an electronic device 1000 may include an application processor 1100, a user interface device 1200, a communication device 1300, a memory device 1400, and the antenna array ATN_ARR. The application processor 1100, the user interface device 1200, the communication device 1300, and the memory device 1400 may be connected to one another through a bus.

In an embodiment, the electronic device 1000 may be the wireless communication device of any type, such as a smartphone, a laptop, a navigation device, or a tablet PC.

The application processor 1100 may control overall operations of the electronic device 1000. For example, the application processor 1100 may control the operations of the user interface device 1200, the communication device 1300, and the memory device 1400.

The user interface device 1200 may support the user in interfacing with the electronic device 1000. For example, the user interface device 1200 may include one or more of user interfacing devices of various types, such as a screen, a keyboard, and the like.

The communication device 1300 may support the communication of the electronic device 1000 with an external device. The communication device 1300 may control the antenna array ATN_ARR. For example, the communication device 1300 may be implemented as the communication device 100 described above with reference to FIGS. 1 to 17. In this case, the communication device 1300 may accurately measure the magnitude of the power emitted from the antenna array ATN_ARR. Therefore, according to an embodiment of the present disclosure, the communication device 1300 may more appropriately adjust the magnitude of the power provided to the antenna array ATN_ARR, thereby improving communication stability of the electronic device 1000 and reducing the power consumption of the electronic device 1000.

The descriptions provided above are the specific embodiments for implementing the present disclosure. The present disclosure may include not only the embodiments described above but also embodiments that may be simply changed in design or easily modified. In addition, the present disclosure may also include techniques that may be easily modified and practiced using the embodiments. Therefore, the spirit of the present disclosure should not be limited to the embodiments described above, and should be defined by the following claims of the present disclosure and their equivalents.

What is claimed is:

1. An operating method of a representative frequency determination device determining a plurality of representative frequencies used by a communication device to estimate total emission power from an antenna array, the method comprising:
generating, based on a first sample communication device corresponding to the communication device, an ideal correction value table including a plurality of ideal correction values respectively corresponding to a plurality of frequencies; and
determining the plurality of representative frequencies such that errors of a plurality of interpolation correction values for the plurality of ideal correction values are less than a threshold error,
wherein the plurality of interpolation correction values are generated by interpolating between a first plurality of ideal correction values, among the plurality of ideal correction values, corresponding to the plurality of representative frequencies.

2. The method of claim 1, wherein the determining is performed based on segmented linear regression analysis.

3. The method of claim 2, wherein the plurality of representative frequencies include:
one or more knot frequencies respectively corresponding to one or more knot points for a plurality of linear regression functions generated by the segmented linear regression analysis.

4. The method of claim 3, wherein each of the one or more knot frequencies is one of the plurality of frequencies.

5. The method of claim 2, wherein the plurality of representative frequencies include:
a maximum frequency among the plurality of frequencies, and
a minimum frequency among the plurality of frequencies.

6. The method of claim 1, wherein the communication device is configured to:
store a plurality of representative correction values measured for the communication device and respectively corresponding to the plurality of representative frequencies.

7. The method of claim 6, wherein the communication device is configured to:
drive the antenna array based on a target frequency;
generate a target interpolation correction value corresponding to the target frequency by interpolating the plurality of representative correction values; and
estimate the total emission power based on the target interpolation correction value.

8. The method of claim 7, wherein the communication device is configured to adjust a power provided to the antenna array based on the estimated total emission power.

9. The method of claim 1, wherein:
the plurality of interpolation correction values respectively correspond to the plurality of frequencies; and
each of the errors corresponds to a difference between an interpolation correction value and an ideal correction value corresponding to a respective one of the frequencies among the plurality of frequencies.

10. A communication device connected to an antenna array including first to k-th antennas, (wherein, k is an integer greater than or equal to 1), the device comprising:
first to k-th amplifiers respectively configured to provide, to the first to k-th antennas, first to k-th amplified input signals which are generated by amplifying the first to k-th input signals having a target frequency;
first to k-th amplifiers respectively configured to provide, to the first to k-th antennas, first to k-th amplified input signals which are generated by amplifying the first to k-th input signals having a target frequency;
first to k-th power detector circuits respectively configured to generate first to k-th detection power values by detecting powers of the first to k-th amplified input signals;
a memory circuit configured to store a first representative correction value corresponding to a first representative frequency less than the target frequency and a second representative correction value corresponding to a second representative frequency greater than the target frequency;
an interpolation circuit configured to calculate a target interpolation correction value corresponding to the target frequency by performing linear interpolation between the first and second representative correction values; and
a gain control circuit configured to control gains of the first to k-th amplifiers based on the target interpolation correction value,
wherein the first and second representative frequencies are determined by segmented linear regression analysis for a plurality of ideal correction values, respectively corresponding to a plurality of frequencies different from each other, of a sample communication device having a same configuration as the communication device.

11. The communication device of claim 10, wherein each of the first and second representative frequencies corresponds to one of:
a knot frequency corresponding to a knot point for a plurality of linear regression functions generated based on the segmented linear regression analysis;
a maximum frequency among the plurality of frequencies; and
a minimum frequency among the plurality of frequencies.

12. The communication device of claim 10, wherein the gain control circuit is configured to:
estimate a total emission power from the antenna array by adding the target interpolation correction value to a sum of the first to k-th detection power values;
generate first to k-th gain control signals based on the estimated total emission power; and
provide the first to k-th gain control signals to the first to k-th amplifiers respectively.

13. The communication device of claim 10, wherein:
the first representative correction value corresponds to a value acquired by subtracting the sum of the first to k-th detection power values from the total emission power from the antenna array when the target frequency is the first representative frequency, and
the second representative correction value corresponds to a value acquired by subtracting the sum of the first to k-th detection power values from the total emission power from the antenna array when the target frequency is the second representative frequency.

14. A representative frequency determination device for determining a plurality of representative frequencies used by a communication device to estimate a total emission power from an antenna array, the representative frequency determination device comprising:
a correction value calculation circuit configured to generate a first ideal correction value table including a first plurality of ideal correction values respectively corresponding to a plurality of frequencies based on a first sample communication device corresponding to the communication device, and to generate a second ideal correction value table including a second plurality of ideal correction values respectively corresponding to the plurality of frequencies based on a second sample communication device corresponding to the communication device;
a representative frequency determination circuit configured to determine a first plurality of representative frequencies based on the first ideal correction value table, and to determine a second plurality of representative frequencies based on the second ideal correction value table; and
a representative frequency merging circuit configured to generate the plurality of representative frequencies based on the first plurality of representative frequencies and the second plurality of representative frequencies.

15. The representative frequency determination device of claim 14, wherein the representative frequency determination circuit is configured to:
determine the first plurality of representative frequencies such that errors of a first plurality of interpolation correction values for the first plurality of ideal correction values are less than or equal to a threshold error;
determine the second plurality of representative frequencies such that errors of a second plurality of interpolation correction values for the second plurality of ideal correction values are less than or equal to the threshold error,
wherein the first plurality of interpolation correction values are generated by interpolating between a plurality of third ideal correction values, among the first plurality of ideal correction values, respectively corresponding to the first plurality of representative frequencies, and
wherein the second plurality of interpolation correction values are generated by interpolating between a plurality of fourth ideal correction values, among the second plurality of ideal correction values, respectively corresponding to the second plurality of representative frequencies.

16. The representative frequency determination device of claim 15, wherein the representative frequency determination circuit is configured to:
determine the first plurality of representative frequencies and the second plurality of representative frequencies based on segmented linear regression analysis.

17. The representative frequency determination device of claim 16, wherein:
the first plurality of representative frequencies include frequencies respectively corresponding to one or more knot points for a first plurality of linear regression functions generated based on the segmented linear regression analysis for the first plurality of ideal correction values, and
the second plurality of representative frequencies include the frequencies respectively corresponding to one or more knot points for a second plurality of linear regression functions generated based on the segmented linear regression analysis for the second plurality of ideal correction values.

18. The representative frequency determination device of claim 14, wherein the representative frequency merging circuit is configured to:
determine the plurality of representative frequencies based on numbers of each frequencies corresponding to the first plurality of representative frequencies and the second plurality of representative frequencies.

19. The representative frequency determination device of claim 14, wherein the communication device, the first sample communication device, and the second sample communication device have the same structure and are produced through the same process.

20. The representative frequency determination device of claim 14, wherein the communication device includes:
a memory circuit configured to store a plurality of representative correction values measured for the communication device and respectively corresponding to the plurality of representative frequencies;
a plurality of antenna driving circuits configured to drive the antenna array based on a target frequency;
an interpolation circuit configured to generate a target interpolation correction value corresponding to the target frequency by interpolating between the plurality of representative correction values; and
a gain control circuit configured to control the plurality of antenna driving circuits based on the total emission power estimated based on the target interpolation correction value.
